(19) United States
(12) Patent Application Publication
(10) Pub. No.: US 2008/0111646 A1
(43) Pub. Date: May 15, 2008

(54) Regulated supply phase locked loop

(76) Inventor: Rajendran Nair, Gilbert, AZ (US)

Correspondence Address: Rajendran Nair, ComLSI Inc., 3838 E. Encinas Ave., Gilbert, AZ, 85234, US

(21) Appl. No.: 11/585,315

(22) Filed: Oct. 24, 2006

(51) Int. Cl. H03L 7/099

(52) U.S. Cl. 331/185

(57) ABSTRACT

A noise-minimizing supply regulation architecture enabling high-performance integrated mixed-signal circuit systems is disclosed. The architecture identifies noise-generating and noise-sensitive sub-components of a PLL or other complex mixed-signal circuit and isolates the noise-sensitive sub-components from the noise-generating sub-components through the use of separate, wideband, high-PSRR voltage regulators for the two isolated supply domains. This isolation is further enhanced through techniques that separate or isolate the substrate regions occupied by the two types of sub-components. Further, internally generated noise is minimized by the allocation of available decoupling capacitance area in proportion to the noise generated within the domains. This supply isolation architecture achieves very low noise operation of the critical components of the mixed-signal integrated circuit system, thereby improving output quality.

### TECHNICAL FIELD OF THE INVENTION

Embodiments of the invention relate to electronic circuitry commonly employed to synthesize or improve clock signals provided to other electronic circuits, devices and systems. Such circuitry falls under the category of Clock Generation and Distribution.

### BACKGROUND & PRIOR ART

Phase locked loop circuits (PLL's) are ubiquitous in the electronics industry. PLLs are extensively employed in communications and computational electronics, and particularly in integrated system-on-chip (SoC) components. As the march of monolithic electronics integration continues and devices and circuits become smaller and faster, PLL's and other mixed-signal circuits and systems are being designed to run at faster and faster frequencies. Communications circuits now operate at billions of bits per second per signal wire or wire pair (Gb/s), requiring clock signals of around the same frequency in many instances. At Gb/s signaling and beyond, channel non-idealities cause substantial signal degradation, leading to distorted and small-value signals at the receiver. In such applications, the accuracy of the time position of clock signals is exceedingly important in the recovery of clock and data signals.

Measures of output or clock position accuracy in a PLL are SKEW and JITTER, where SKEW is a static or time-invariant differential w.r.t. an ideal clock position and JITTER is the time-dependent error of the clock signal transition w.r.t. and ideal clock. PLL's are commonly employed to assist in improving the quality of a clock signal via de-skewing and de-jittering functions. Despite this capability, PLL's inherently generate and contribute to skew and jitter because of the non-idealities of its devices and circuits as well as the operating environment. PLL's are particularly susceptible to power supply noise, and in instances of monolithic integration, to substrate noise as well. Noise components in the supply and the substrate directly impact JITTER. In particular, the oscillator sub-component of PLL's, the VCO (voltage controlled oscillator), which converts a voltage bias value into a frequency with high gain, is particularly susceptible to supply and substrate noise. This susceptibility has led to PLL architectures in the art that regulate the supply voltage provided to the PLL.

Prior art supply voltage regulation to PLL's takes two principal forms:
1. Regulation of the supply voltage to the entire PLL circuit
2. A supply-regulated VCO, where the supply voltage of the VCO also acts as the voltage bias controlling the frequency output of the VCO

Both these architectures have advantages and inherent limitations. As operating frequencies and the speed at which digital circuits change state increase, substantial noise is generated internal to the PLL circuit and supply grid due to the digital circuits that are often part of the circuit. For example, typical dividers employed in a PLL use high-bandwidth digital flip-flops to divide the high frequency signal generated by the VCO, and these flip flops generate very substantial internal or local DI/DT (rate of change of current) that induces substantial noise within the supply grid of the PLL. Phase-frequency detectors are also often implemented using logic gates with corresponding local noise generated by these circuits. Noise propagates rapidly within the common supply grid of the PLL, impacting the VCO and causing JITTER. The second architecture employing supply regulation for the VCO has a limited range of operation at low supply voltages while potentially introducing an undesirable bandwidth mismatch between the control bias generation circuits and the VCO.

### INVENTION SUMMARY

The invention supply regulation architecture addresses these deficiencies by isolating noise-generating digital sub-circuits of a PLL on a separate regulated supply grid from the regulated supply grid that powers the VCO and associated analog sub-circuits. The split supply grid combines with isolation wells between the two domains, providing a substantial measure of substrate-noise isolation as well. Regulators with high PSRR of approximately 30 dB or greater across the entire spectrum of noise frequencies are employed to supply power to the isolated voltage domains. Total available decoupling capacitance area is divided in proportion to the noise generated within each domain and connected within the domains. Very low noise, both in the supply as well as the substrate connecting to critical circuits minimizes PLL jitter in this invention architecture.

### BRIEF DESCRIPTION OF THE FIGURES

FIG. 1 illustrates s prior art unregulated supply architecture for a PLL.

FIG. 2 is an illustration of prior art regulated supply PLL.

FIG. 3 is a prior art alternate regulated supply PLL.

FIG. 4 illustrates an architectural embodiment of the invention.

### DETAILED DESCRIPTION

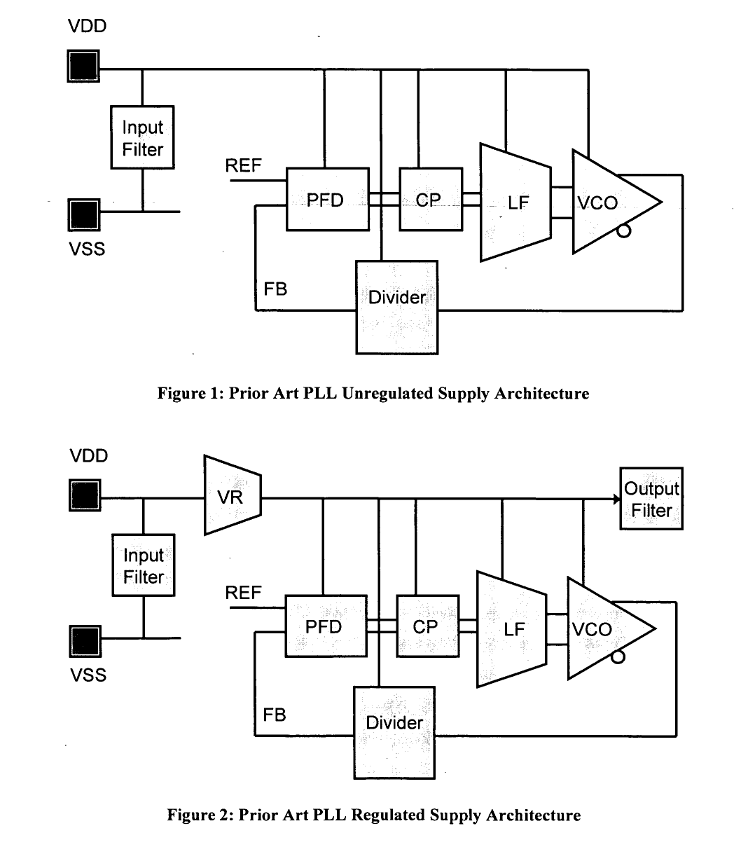

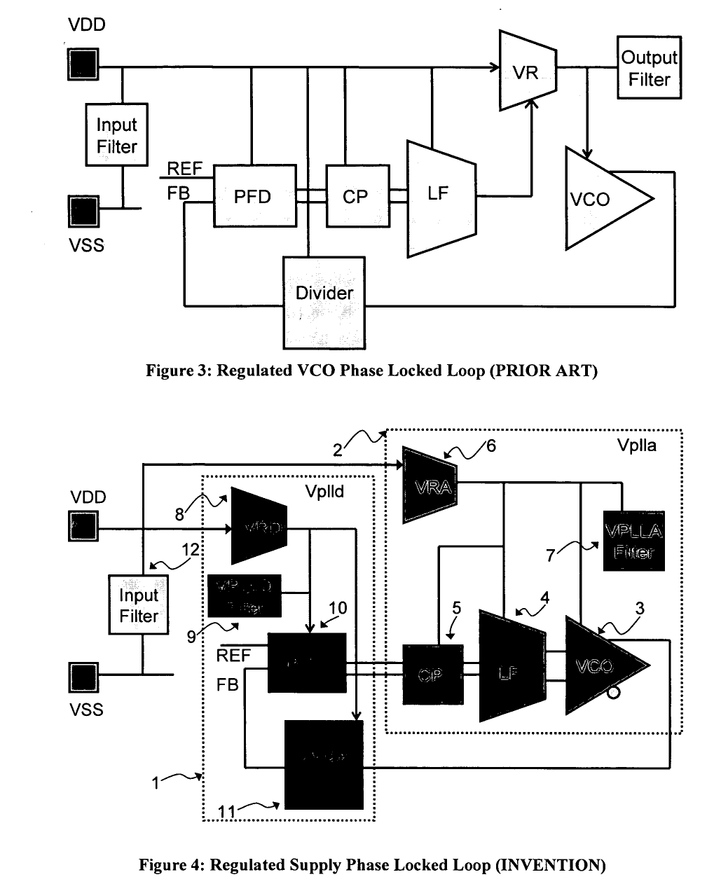

Prior art embodiments are illustrated in FIGS. 1, 2 and 3. As described in the background, two forms of supply regulation are common in the art. FIG. 2 shows the typical supply regulated PLL, where the operating supply for the PLL is derived from a voltage regulated version of an input supply voltage. Buck, linear regulators are commonly used in this architecture. FIG. 3 illustrates another prior art supply regulated PLL where the operating supply voltage of the VCO (or oscillatory component) of the PLL is regulated, and also serves as the control that determines the output frequency of the VCO. In this architecture, the regulator becomes a key component in the control loop of the PLL, and its characteristics are designed so as to achieve desired loop behavior as well as to minimize jitter induced in the output of the VCO.

FIG. 4 shows an embodiment of the invention. In this supply regulation architecture, PLL sub-components are classified as being either noise-generating or noise-sensitive components, and the power supply grid within the PLL is split in order to separate these component classifications from each other.

A typical PLL consists of a phase-frequency detector (PFD), a charge pump (CP), a loop filter (LF), a voltage-controlled oscillator (VCO) and a divider (DIV). Of these sub-components, the PFD and DIV typically consist of digital circuits that can induce substantial noise into their power supply network because of crow-bar and signal transition related charging and discharging currents. Contrastingly, the CP, LF and VCO blocks often operate with static bias currents that are channeled differentially through load devices, and generate little to no noise. Additionally, the VCO is perhaps the most sensitive to power supply and substrate noise in terms of output jitter.

The invention architecture recognizes this distinction between the sub-components of a PLL or any mixed-signal circuit system, and isolates the set of noise-generating components from the set of noise-sensitive components through the use of two distinct voltage regulators. In FIG. 4, sub-components 8, 9, 10 and 11 form a separate voltage domain ‘VPLLD’ and sub-components 3 to 7 similarly form another distinct voltage domain ‘VPLLA’. Sub-component 8 derives an input voltage from a common supply pin VDD and provides a regulated supply to the VPLLD supply domain and sub-component 6 similarly provides a regulated supply voltage to the VPLLA domain. The two supply voltage domains are unconnected to each other and may be different in their static values from each other. Signal communication from one supply domain to the other may be done differentially in order to avoid performance degradation; the PFD provides differential output signals to the CP in the invention architecture.

In addition to the isolation of the two classifications of sub-components, circuits within the two supply voltage domains are also physically isolated from each other in the invention architecture to the extent possible. Where the PLL is implemented in a twin-well CMOS process, for example, these circuits are isolated from each other through the use of n-type and p-type guard rings. Triple well and SOI (silicon-on-insulator) processes offer much greater isolation diminishing the need for such guard rings.

The voltage regulators in the invention architecture are designed to be circuits demonstrating excellent power supply rejection ratio (PSRR) over the entire spectrum of operational and noise frequencies. Such voltage regulation blocks the transmission of noise energy from the input supply pin (VDD) into the supply voltage domains of the PLL. In a specific embodiment, linear buck regulators with PSRR greater than or equal to about 30 dB have been employed for this purpose.

All PLL's are associated with a certain amount of ‘supply de-coupling’ capacitance employed to ensure a degree of noise minimization within the supply grid of the PLL. In the invention architecture, available capacitance area is distributed between the two supply domains approximately in proportion with the noise generated by the subcomponents within the domains. This helps in minimizing internally generated noise by making available sufficient capacitance at the noise-generating sections of the PLL.

It will be evident to one skilled in the art that the separation of the two supply voltage domains minimizes the impact of noise generated by specific sub-components in the PLL upon the noise-sensitive subcomponents within, leading to lesser JITTER at the output of the VCO. Simultaneously, the presence of voltage regulators minimizes the impact of ‘input noise’ into the regulated supply PLL. The invention architecture therefore addresses and effectively isolates external and internal noise from impacting critical circuits of the PLL.

It may also be understood by one skilled in the art that the supply isolation architecture disclosed in the invention may be employed to similar benefits in any mixed-signal system that contains noise-generating and noise-sensitive components, and that the architecture is therefore not limited in its use or advantage to phase-locked loops.

Although specific embodiments are illustrated and described herein, any circuit arrangement configured to achieve the same purposes and advantages may be substituted in place of the specific embodiments disclosed. This disclosure is intended to cover any and all adaptations or variations of the embodiments of the invention provided herein. All the descriptions provided in the specification have been made in an illustrative sense and should in no manner be interpreted in any restrictive sense. The scope, of various embodiments of the invention whether described or not, includes any other applications in which the structures, concepts and methods of the invention may be applied. The scope of the various embodiments of the invention should therefore be determined with reference to the appended claims, along with the full range of equivalents to which such claims are entitled. Similarly, the abstract of this disclosure, provided in compliance with 37 CFR §1.72(b), is submitted with the understanding that it will not be interpreted to be limiting the scope or meaning of the claims made herein. While various concepts and methods of the invention are grouped together into a single ‘best-mode’ implementation in the detailed description, it should be appreciated that inventive subject matter lies in less than all features of any disclosed embodiment, and as the claims incorporated herein indicate, each claim is to viewed as standing on it's own as a preferred embodiment of the invention.

What is claimed is:

1. An integrated circuit apparatus, comprising:
a first voltage regulator with an input and a first output connecting to the common power supply node of a first set of sub-circuits;
a second voltage regulator with an input and a second output connecting to the common power supply node of a second set of sub-circuits;
a power supply input, connecting to the inputs of the first and second voltage regulators;
where the first set of sub-circuits and the second set of sub-circuits contain sub-components of the same mixed-signal integrated circuit system and the common power supply node of the first set of sub-circuits is not directly connected to the common power supply node of the second set of sub-circuits.

2. The apparatus of claim 1 where the mixed-signal circuit is a phase-locked loop.

3. The apparatus of claim 1 where the first set of sub-circuits include the phase-frequency detector and the frequency divider of a phase-locked loop and the second set of sub-circuits include the charge pump, the loop filter and the voltage-controlled oscillator of the phase-locked loop.

4. The apparatus of claim 1 where the output of either the first or the second voltage regulator connects to the common power node of the digital sub-components of a mixed-signal circuit system and the output of the other voltage regulator connects to the common power node of the analog sub-components of the mixed-signal circuit system.

5. The apparatus of claim 1 where the first and second voltage regulators are linear, voltage down-conversion regulators with high power supply rejection ratio.

6. The apparatus of claim 1 where the first output of the first voltage regulator connects to a first bank of decoupling capacitors, and the second output of the second voltage regulator connects to a distinct second bank of decoupling capacitors, where the ratio of the capacitance value of the first bank of decoupling capacitors to the capacitance value of the second bank of decoupling capacitors corresponds to the ratio of the power supply noise generated by the first set of sub-circuits to the power supply noise generated by the second set of sub-circuits.

7. The apparatus of claim 1 where the output voltage of the first voltage regulator is not equal to the output voltage of the second voltage regulator.

8. The apparatus of claim 1 where the first voltage regulator and the sub-circuits connecting to it are grouped in close proximity to each other, and fabricated on a silicon chip a finite distance away from the second voltage regulator and the sub-circuits connecting to it, which are similarly grouped in close proximity as fabricated on the silicon chip.

9. The apparatus of claim 1 fabricated on a CMOS chip, where the first voltage regulator and the sub-circuits connecting to it are grouped in close proximity to each other in a first group, and the second voltage regulator and the sub-circuits connecting to it are grouped in close proximity to each other in a second group, with the first group and the second group isolated from each other by means of n-type, or p-type, or both types of guard rings surrounding the first and the second groups.

10. The apparatus of claim 1, where the first set of sub-circuits are noise generating circuits and the second set of sub-circuits are noise-sensitive circuits.

11. Electronic systems comprised of various integrated and discrete electronic circuits and devices, electro-chemical, electro-thermal, electro-mechanical and electro-optic devices that employ the apparatus of claim 1 in any embodiment.
